(19) United States
(12) Patent Application Publication
(10) Pub. No.: US 2011/0051536 A1
(43) Pub. Date: Mar. 3, 2011

(54) SIGNAL DELAY CIRCUIT AND A SEMICONDUCTOR MEMORY DEVICE HAVING THE SAME

(76) Inventor: Sang-kyun Park, Gyeonggi-do (KR)

(21) Appl. No.: 12/797,832

(22) Filed: Jun. 10, 2010

(30) Foreign Application Priority Data
Aug. 27, 2009 (KR) 10-2009-0079764

(51) Int. Cl. G11C 7/00; H03L 7/00

(52) U.S. Cl. 365/194; 327/161

(57) ABSTRACT

A signal delay circuit that includes a delay unit configured to delay an input signal for a first delay time and output the delayed input signal; a first delay adjusting unit configured to adjust the first delay time according to a variation in a level of a power supply voltage supplied to the delay unit; and a second delay adjusting unit configured to offset an amount of time the first delay time is adjusted by the first delay adjusting unit.

### CROSS-REFERENCE TO RELATED APPLICATION

This application claims priority under 35 U.S.C. §119 to Korean Patent Application No. 10-2009-0079764, filed on Aug. 27, 2009, in the Korean Intellectual Property Office, the disclosure of which is incorporated by reference herein in its entirety.

### BACKGROUND

1. Technical Field

The inventive concept relates to signal delay circuits and semiconductor memory devices that employ signal delay circuits, and more particularly, to a signal delay circuit that is capable of stably delaying a signal, regardless of a level of a voltage that is supplied from an external source, and a semiconductor memory device having the signal delay circuit.

2. Discussion of Related Art

Semiconductor memory devices that are manufactured with scaled-down process technologies and that consume low power may run on an adjustable voltage supplied from an external source. In fact, such devices may use the voltage supplied from the external source directly as an internal operating voltage. However, in this case, a delay between internal signals can be distorted due to a change in a level of the voltage supplied to the semiconductor memory device, such that the semiconductor memory device may malfunction.

Accordingly, there is a need to prevent a delay between internal signals of a semiconductor memory device from being distorted.

### SUMMARY

According to an exemplary embodiment of the inventive concept, there is provided a signal delay circuit including a delay unit configured to delay an input signal for a first delay time and output the delayed input signal; a first delay adjusting unit configured to adjust the first delay time according to a variation in a level of a power supply voltage supplied to the delay unit; and a second delay adjusting unit configured to offset an amount of time the first delay time is adjusted by the first delay adjusting unit.

The delay unit may include a plurality of inverters that are connected in series, a first of the series connected inverters being enabled by the input signal or an inverted version of the input signal.

The first delay adjusting unit may include a resistor that is connected between the power supply voltage and at least one of the plurality of inverters, or connected between a ground voltage and at least one of the plurality of inverters, wherein a resistance of the resistor varies according to the variation in the voltage level of the power supply voltage.

The resistance of the resistor may decrease when the power supply voltage increases and increase when the power supply voltage decreases.

The second delay adjusting unit may include a first metal-oxide-semiconductor (MOS) capacitor and a second MOS capacitor that are connected in series between a ground voltage and an output of at least one of the plurality of inverters, or connected in series between the power supply voltage and an output of at least one of the plurality of inverters. Here, a resultant capacitance of the first MOS capacitor and the second MOS capacitor may linearly increase while the power supply voltage is shifted from a low voltage level to a high voltage level.

The first delay time may be obtained by multiplying the resistance of the resistor by the resultant capacitance of the first and second MOS capacitors.

The first delay adjusting unit may include a resistor that is connected between a ground voltage and at least one of the plurality of inverters, wherein a resistance of the resistor varies according to the variation in the voltage level of the power supply voltage.

The second delay adjusting unit may include a first MOS capacitor and a second MOS capacitor that are connected in series between the ground voltage and an output of at least one of the plurality of inverters.

The second delay adjusting unit may include a first MOS capacitor through an m^{th} (m is an integer equal to or greater than 3) MOS capacitor that are connected in series between the ground voltage and an output of a last of the series connected inverters that outputs the delayed input signal.

The first delay adjusting unit may include a resistor string connected between a ground voltage and a last of the series connected inverters.

The first delay adjusting unit may include a resistor that is connected between the power supply voltage and at least one of the plurality of inverters, wherein a resistance of the resistor varies according to the variation in the voltage level of the power supply voltage.

The second delay adjusting unit may include a first MOS capacitor and a second MOS capacitor that are connected in series between the power supply voltage and an output of at least one of the plurality of inverters.

The first delay adjusting unit may include a first resistor that is connected between the power supply voltage and at least one of the plurality of inverters; and a second resistor that is connected between a ground voltage and at least one of the plurality of inverters to which the first register is not connected.

The second delay adjusting unit may include a first MOS capacitor and a second MOS capacitor that are connected in series between the ground voltage and an output of at least one of the plurality of inverters; and a third MOS capacitor and a fourth MOS capacitor that are connected in series between the power supply voltage and an output of at least one of the plurality of inverters to which the first MOS capacitor and the second MOS capacitor are not connected.

The power supply voltage may be directly supplied to the signal delay circuit from an external source of a device including the signal delay circuit.

According to an exemplary embodiment of the inventive concept, there is provided a signal delay circuit including a plurality of unit signal delay circuits that are connected in series. Here, each of the unit signal delay circuits includes a delay unit configured to delay an input signal for a first delay time and output the delayed input signal; a first delay adjusting unit configured to adjust the first delay time according to a variation in a level of a power supply voltage supplied to the delay unit; and a second delay adjusting unit configured to offset an amount of time the first delay time is adjusted by the first delay adjusting unit.

The first delay time of a unit signal delay circuit may be the same as the first delay time of another unit signal delay circuit, or the first delay time of a unit signal delay circuit may be different than the first delay time of another unit signal delay circuit.

According to an exemplary embodiment of the inventive concept, there is provided a semiconductor memory device that includes a memory cell array and a signal delay circuit, wherein the signal delay circuit includes a delay unit configured to delay an input signal for a first delay time and output the first delayed input signal; a first delay adjusting unit configured to adjust the first delay time according to a variation in a voltage level of a power supply voltage supplied to the delay unit; and a second delay adjusting unit configured to offset an amount of time the first delay time is adjusted by the first delay adjusting unit, wherein the semiconductor memory device reads data from the memory cell array or stores data in the memory cell array in response to the signal output from the signal delay circuit.

The semiconductor memory device may be included in a computing system.

### BRIEF DESCRIPTION OF THE DRAWINGS

The above and other features of the inventive concept will become more apparent by describing in detail exemplary embodiments thereof with reference to the accompanying drawings in which:

FIG. 1 is a block diagram of a signal delay circuit according to an exemplary embodiment of the inventive concept;

FIG. 2 is a circuit diagram of an exemplary embodiment of the signal delay circuit of FIG. 1;

FIG. 3 is a circuit diagram of an inverter of FIG. 2;

FIG. 4 is a diagram exhibiting capacitance characteristics of a first metal-oxide-semiconductor (MOS) capacitor and a second MOS capacitor of FIG. 2;

FIG. 5A is a diagram of a first delay time variation due to a power supply voltage variation in a conventional signal delay circuit, and FIG. 5B is a diagram of a first delay time in the signal delay circuit of FIG. 1, wherein the first delay time has a fixed value regardless of a power supply voltage variation;

FIGS. 6A and 6B are circuit diagrams of exemplary embodiments of the signal delay circuit of FIG. 1;

FIG. 7 is a circuit diagram of an exemplary embodiment of the signal delay circuit of FIG. 1;

FIG. 8 is a circuit diagram of an exemplary embodiment of the signal delay circuit of FIG. 1;

FIG. 9 is a circuit diagram of an exemplary embodiment of the signal delay circuit of FIG. 1;

FIG. 10 is a block diagram of a signal delay circuit according to an exemplary embodiment of the inventive concept;

FIG. 11 is a circuit diagram of an exemplary embodiment of the signal delay circuit of FIG. 10; and

FIG. 12 is a block diagram of a computing system apparatus including a semiconductor memory device having a signal delay circuit according to an exemplary embodiment of the inventive concept.

### DETAILED DESCRIPTION OF THE EMBODIMENTS

Exemplary embodiments of the inventive concept are described more fully hereinafter with reference to the attached drawings. Like reference numerals in the drawings denote like elements.

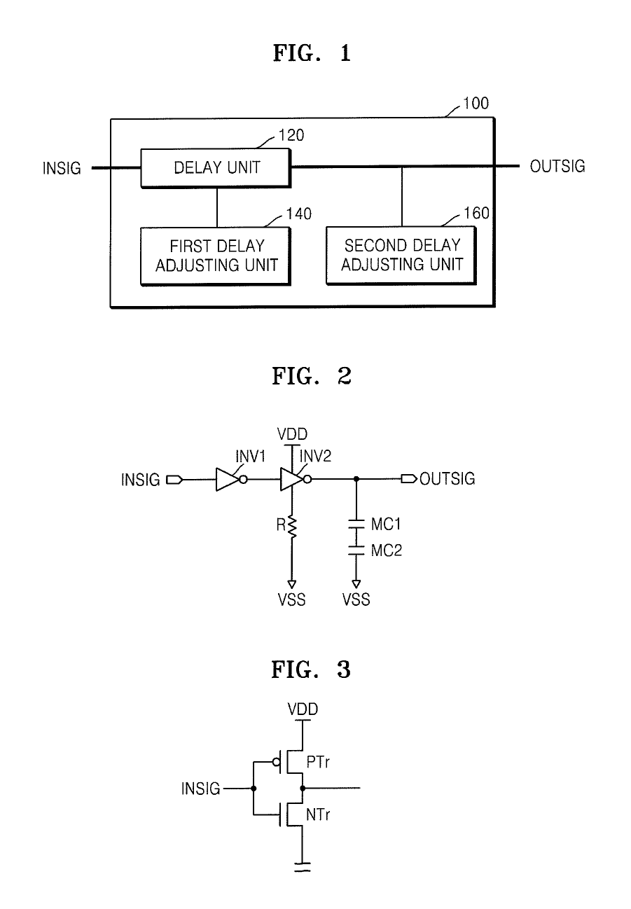

FIG. 1 is a block diagram of a signal delay circuit 100 according to an exemplary embodiment of the inventive concept. FIG. 2 is a circuit diagram of an exemplary embodiment of the signal delay circuit 100 of FIG. 1.

Referring to FIGS. 1 and 2, the signal delay circuit 100 according to the present exemplary embodiment includes a delay unit 120, a first delay adjusting unit 140, and a second delay adjusting unit 160.

The delay unit 120 receives an input signal INSIG, delays the input signal INSIG by a first delay time, and outputs an output signal OUTSIG. The input signal INSIG may include various signals such as a read command and a write command that may be used in a semiconductor memory device.

As illustrated in FIG. 2, the delay unit 120 may be embodied as two inverters INV1 and INV2 that are connected in series.

Referring to FIG. 2, the delay unit 120 includes only the two inverters INV1 and INV2 connected in series; however, a structure of the delay unit 120 is not limited thereto. As will be described later, the delay unit 120 may include three or more inverters that are connected in series.

As illustrated in FIG. 3, the inverters INV1 and INV2 are connected in series, and each may include a p-type metal-oxide-semiconductor (PMOS) transistor PTr and an n-type metal-oxide-semiconductor (NMOS) transistor NTr connected in series and gated by the input signal INSIG or an inverted version of the input signal INSIG. The PMOS transistor PTr is turned on by the input signal INSIG when the input signal INSIG is logic low “L”, and the NMOS transistor NTr is turned on by the input signal INSIG when the input signal INSIG is logic high “H”. In a transition period where the input signal INSIG transits logic levels, on/off of the PMOS transistor PTr and the NMOS transistor NTr transit such that the input signal INSIG may be delayed and then output.

An end of the PMOS transistor PTr is connected to a power supply voltage VDD, and an end of the NMOS transistor NTr (of one of the invertors, for example, the inverter INV2,) is connected to the first delay adjusting unit 140.

The first delay adjusting unit 140 may be positioned between the NMOS transistor NTr of the inverter INV2 and a ground voltage VSS, and may be a resistor R whose resistance varies according to the power supply voltage VDD. Referring to FIG. 2, the first delay adjusting unit 140 includes only the one resistor R; however, a structure of the first delay adjusting unit 140 is not limited thereto and thus the first delay adjusting unit 140 may be embodied as a resistor string including a plurality of resistors, as will be described later.

If the power supply voltage VDD increases, resistance of the resistor R decreases. On the other hand, if the power supply voltage VDD decreases, the resistance of the resistor R increases. This is because such variation of the power supply voltage VDD changes a driving ability of the inverter INV2, such that an amount of current flowing to the resistor R connected to the inverter INV2 varies.

In this manner, the first delay adjusting unit 140 has a resistance that varies according to the power supply voltage VDD supplied to the delay unit 120, and thus the first delay adjusting unit 140 may adjust the first delay time. However, the first delay time has to be maintained at a fixed value to allow the output signal OUTSIG to be stably generated, when the output signal OUTSIG is used as an internal operating signal of a semiconductor memory device. In a situation in which a voltage supplied from an external source is decreased from a high level to a low level, for example, if the voltage is directly used as the internal operating voltage of the semiconductor memory device, malfunctions due to the change in the power supply voltage VDD may occur.

The signal delay circuit 100 according to the present exemplary embodiment, however, includes the second delay adjusting unit 160 capable of keeping the first delay time at a fixed value even when a value of the power supply voltage VDD that is supplied to the delay unit 120 varies.

The second delay adjusting unit 160 offsets an amount of time by which the first delay time is adjusted by the first delay adjusting unit 140, and thus may constantly maintain the first delay time. As illustrated in FIG. 2, the second delay adjusting unit 160 may be embodied as a first MOS capacitor MC1 and a second MOS capacitor MC2 that are positioned between an output node of the delay unit 120 and a ground voltage VSS and that are connected in series. A MOS capacitor may be formed by connecting a source and drain of a MOS transistor.

Referring to FIG. 2, the second delay adjusting unit 160 only includes two MOS capacitors, in other words, the first and second MOS capacitors MC1 and MC2; however, a structure of the second delay adjusting unit 160 is not limited thereto and thus, as will be described later, the second delay adjusting unit 160 may be embodied as three or more MOS capacitors that are connected in series.

Referring to FIG. 2, the first and second MOS capacitors MC1 and MC2 of the second delay adjusting unit 160 have the same capacitance. However, the second delay adjusting unit 160 is not limited thereto, and thus may have a first MOS capacitor having a capacitance that is greater or less than a capacitance of a second MOS capacitor.

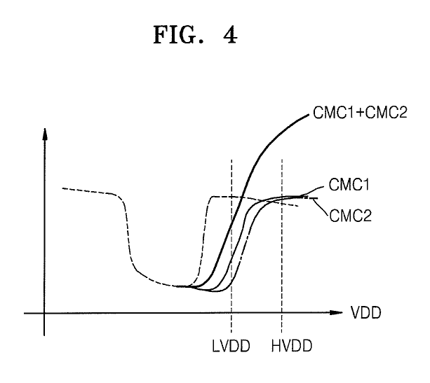

Capacitance characteristics of the first MOS capacitor MC1 and the second MOS capacitor MC2 connected in series are described below with reference to FIG. 4.

Referring to FIG. 4, the capacitance characteristics of the first MOS capacitor MC1 and the second MOS capacitor MC2 may both be illustrated as a dashed line in FIG. 4. When the first and second MOS capacitors MC1 and MC2 are connected in series, the first and second MOS capacitors MC1 and MC2 have capacitance characteristics that are different and may be shown as a first MOS capacitor MC1 line CMC1 and a second MOS capacitor MC2 line CMC2 in FIG. 4. In addition, a resultant capacitance of the first MOS capacitor MC1 and the second MOS capacitor MC2 connected in series has capacitance characteristics shown as a CMC1+CMC2 line in FIG. 4.

Examining the capacitance characteristics of the first MOS capacitor MC1 and the second MOS capacitor MC2 when they are connected in series, it is possible to see that the capacitance characteristics of the first MOS capacitor MC1 and the second MOS capacitor MC2 have linearity between a low power supply voltage LVDD having a low voltage level and a high power supply voltage HVDD having a high voltage level. More specifically, capacitance of the second delay adjusting unit 160 increases when the power supply voltage VDD increases, and decreases when the power supply voltage VDD decreases.

The first delay time may be determined by multiplying the resistance of the first delay adjusting unit 140 and the capacitance of the second delay adjusting unit 160 together. Thus, although the resistance decreases when the power supply voltage VDD increases and the resistance increases when the power supply voltage VDD decreases, since the capacitance increases when the power supply voltage VDD increases and the capacitance decreases when the power supply voltage VDD decreases, the first delay time may have the fixed value.

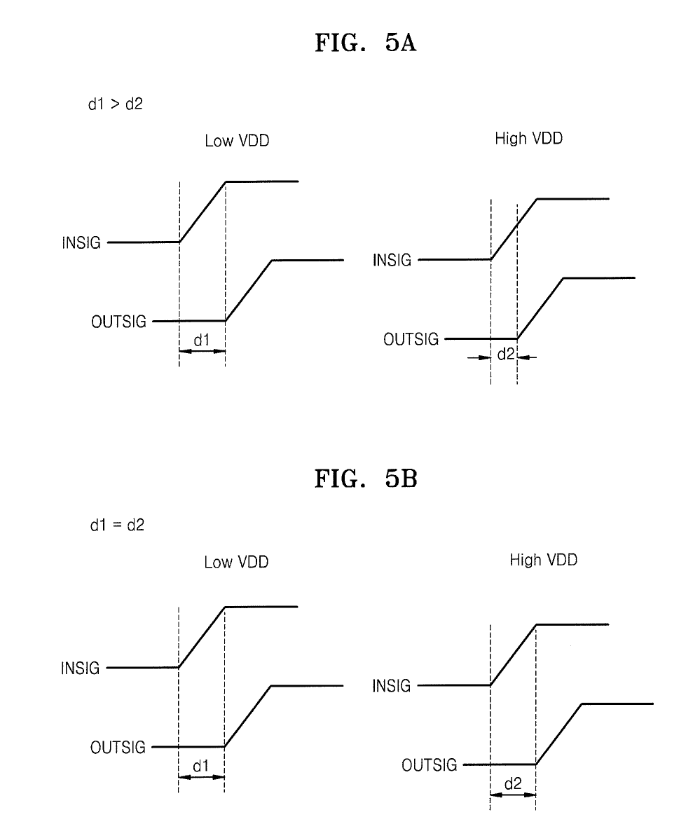

FIG. 5A is a diagram of a first delay time variation due to a power supply voltage variation in a conventional signal delay circuit, and FIG. 5B is a diagram of the first delay time in the signal delay circuit 100 of FIG. 1, wherein the first delay time is maintained at the fixed value regardless of a power supply voltage variation.

Referring to FIG. 5A, in the conventional signal delay circuit, it is possible to see that a first delay time dl at a low level power supply voltage Low VDD is longer than a first delay time d2 at a high level power supply voltage High VDD. On the other hand, referring to FIG. 5B, in the signal delay circuit 100 of FIG. 1, it is possible to see that a first delay time d1 at a low level power supply voltage Low VDD is equal to a first delay time d2 at a high level power supply voltage High VDD.

In this manner, in the case where the power supply voltage supplied from an external source is directly used as an internal operating voltage of a semiconductor memory device, the signal delay circuit 100 of FIG. 1 may maintain a constant delay time even when the power supply voltage varies. Accordingly, it is possible to prevent variations in the power supply voltage that may cause the semiconductor memory device to malfunction.

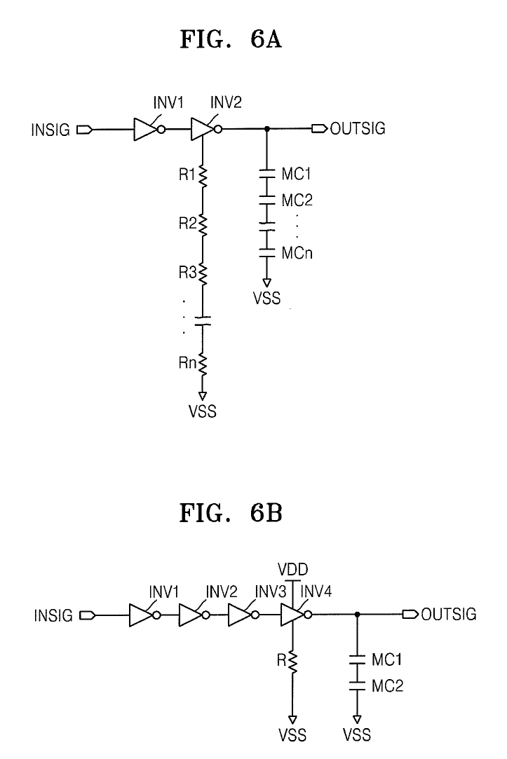

FIGS. 6A and 6B are circuit diagrams of exemplary embodiments of the signal delay circuit 100 of FIG. 1.

Referring to FIGS. 1 and 6A, the delay unit 120 of FIG. 1 is embodied as two inverters INV1 and INV2 that are connected in series, in the same manner as shown in FIG. 2. However, in the exemplary embodiment in FIG. 6A, the first delay adjusting unit 140 may be embodied as a plurality of resistors R1, R2, . . . , Rn that are connected in series, and the second delay adjusting unit 160 may be embodied as three or more MOS capacitors MC1, MC2, . . . , MCm that are connected in series.

Referring to FIGS. 1 and 6B, with respect to the first delay adjusting unit 140 and the second delay adjusting unit 160 of FIG. 1, the first delay adjusting unit 140 is embodied as a resistor R, and the second delay adjusting unit 160 is embodied as a first MOS capacitor MC1 and a second MOS capacitor MC2 connected in series, in the same manner as shown in FIG. 2. However, in the exemplary embodiment in FIG. 6B, the delay unit 120 may be embodied as four or more inverters INV1˜INV4 that are connected serially.

The signal delay circuit 100 of FIG. 1 having a structure illustrated in FIGS. 6A and 6B also offsets a variation in an amount of resistance by reciprocally varying an amount of capacitance, and thus may maintain a constant first delay time regardless of a variation of a power supply voltage VDD. In other words, the resistance decreases when the power supply voltage VDD increases and the resistance increases when the power supply voltage VDD decreases, and the capacitance increases when the power supply voltage VDD increases and the capacitance decreases when the power supply voltage VDD decreases.

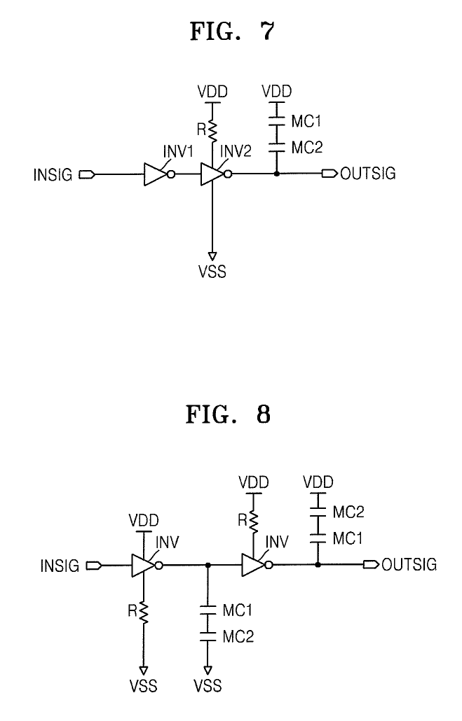

The signal delay circuit 100 of FIG. 1 having the structure illustrated in FIG. 1 or FIGS. 6A and 6B may perform a delay operation on the input signal INSIG when the input signal INSIG is transited from logic low “L” to logic high “H”. On the other hand, in the case of the signal delay circuit 100 of FIG. 1 having a structure illustrated in FIG. 7, which illustrates an exemplary embodiment of the signal delay circuit 100 of FIG. 1, the signal delay circuit of FIG. 7 may perform a delay operation on an input signal INSIG when the input signal INSIG is transited from logic high “H” to logic low “L”.

Referring to FIG. 1 and FIG. 7, the delay unit 120 of FIG. 1 is embodied as two inverters INV1 and INV2 that are connected in series, in the same manner as shown in FIG. 2. However, in the exemplary embodiment in FIG. 7, the first delay adjusting unit 140 includes a resistor R that is connected between a power supply voltage VDD and a PMOS transistor of the inverter INV2, and the second delay adjusting unit 160 includes a first MOS capacitor MC1 and a second MOS capacitor MC2 that are connected in series between the power supply voltage VDD and an output of the inverter INV2.

Since the resistor R of the first delay adjusting unit 140, and the first MOS capacitor MC1 and the second MOS capacitor MC2 of the second delay adjusting unit 160 are not connected to a ground voltage VSS as illustrated in FIG. 2, but are connected to the power supply voltage VDD, the delay operation on the input signal INSIG may be performed when the input signal INSIG is transited from logic high “H” to logic low “L”.

In addition, referring to FIG. 1 and FIG. 8, which illustrates an exemplary embodiment of the signal delay circuit 100 of FIG. 1, each of the two inverters INV1 and INV2 forming the delay unit 120 of FIG. 1 may include the first delay adjusting unit 140 and the second delay adjusting unit 160. Here, the first delay adjusting unit 140 and the second delay adjusting unit 160 included in the inverter INV1 are respectively embodied as a resistor R connected to a ground voltage VSS and as a first MOS capacitor MC1 and a second MOS capacitor MC2 connected to the ground voltage VSS, in the same manner as shown in FIG. 2. On the other hand, the second inverter INV2 includes a resistor R connected to a power supply voltage VDD, and a first MOS capacitor MC1 and a second MOS capacitor MC2 connected to the power supply voltage VDD, in the same manner as shown in FIG. 7.

Accordingly, in the case where the signal delay circuit 100 of FIG. 1 is embodied in a manner as illustrated in FIG. 8, the signal delay circuit 100 of FIG. 1 embodied as shown in FIG. 8 may perform a delay operation on an input signal INSIG in both cases where the input signal INSIG is transited from logic low “L” to logic high “H” and where the input signal INSIG is transited from logic high “H” to logic low “L”.

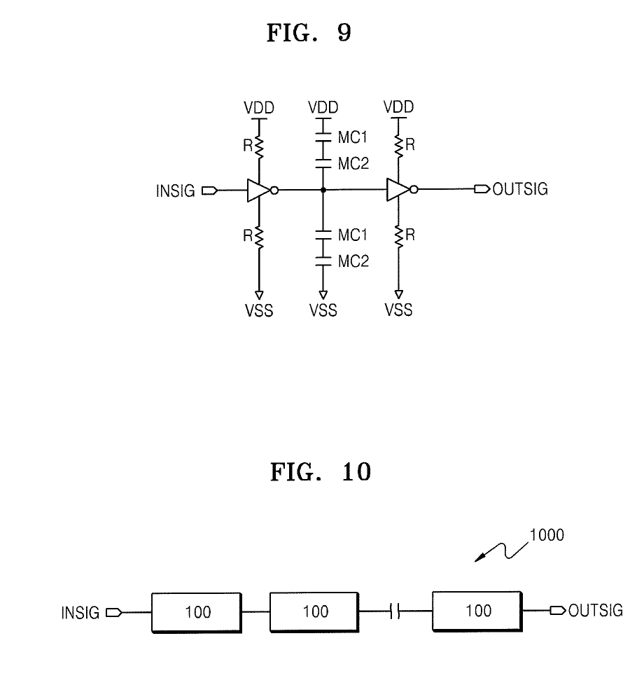

In addition, in the case of FIG. 9, which illustrates an exemplary embodiment of the signal delay circuit 100 of FIG. 1, the signal delay circuit 100 of FIG. 1 embodied as shown in FIG. 9 may perform a delay operation on an input signal INSIG in both cases where the input signal INSIG is transited from logic low “L” to logic high “H” and where the input signal INSIG is transited from logic high “H” to logic low “L”.

Unlike the exemplary embodiment in FIG. 8, in the exemplary embodiment in FIG. 9, a first MOS capacitor MC1 and a second MOS capacitor MC2 that are connected to a first inverter INV1 and a first MOS capacitor MC1 and a second MOS capacitor MC2 that are connected to a second inverter INV2 are all connected to the same node.

FIG. 10 is a block diagram of a signal delay circuit 1000 according to an exemplary embodiment of the inventive concept.

Referring to FIG. 10, the signal delay circuit 1000 is formed by connecting a plurality of the signal delay circuits 100 of FIG. 1 in series. To avoid confusion, the signal delay circuit 100 of FIG. 1 is referred to as a unit signal delay circuit 100.

Each of the unit signal delay circuits 100 included in the signal delay circuit 1000 of FIG. 10 may be embodied as any of the example signal delay circuits illustrated in FIGS. 2, 6, 7, and 8. Times delayed by the unit signal delay circuits 100 may be different from each other.

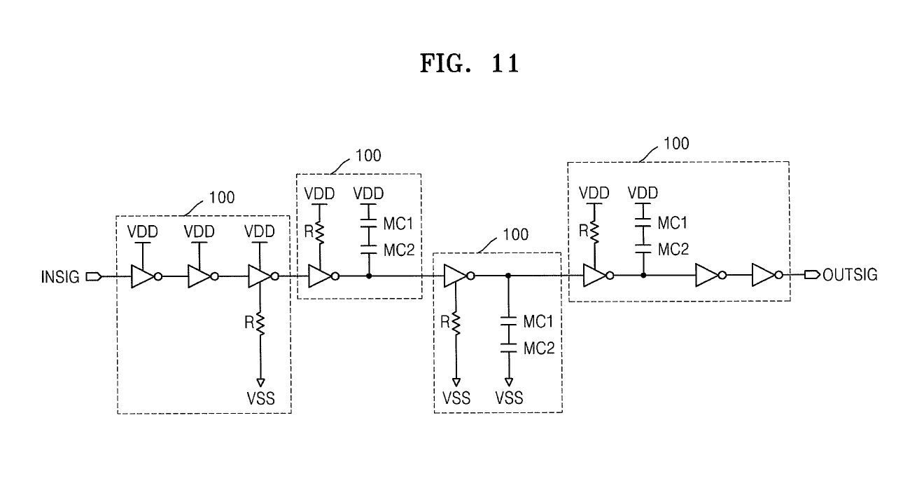

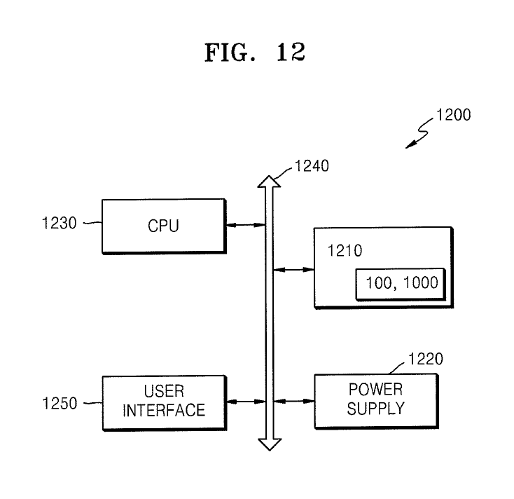

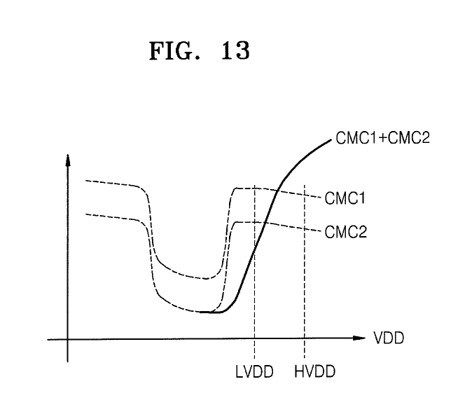

In addition, as shown in FIG. 11, which illustrates an exemplary embodiment of the signal delay circuit 1000 of FIG. 10, the unit signal delay circuits 100 may be embodied as a combination of the example signal delay circuits of FIGS. 2, 6, 7 and 8. Referring to FIG. 11, to generate an output signal OUTSIG having the same logic level as that of an input signal INSIG, the number of inverters may be adjusted.

FIG. 12 is a block diagram of a computing system apparatus 1200 including a semiconductor memory device 1210 having a signal delay circuit according to an exemplary embodiment of the inventive concept.

As illustrated in FIG. 12, the computing system apparatus 1200 according to the present exemplary embodiment may include a power supply 1220, a central processing unit (CPU) 1230 electrically connected to a bus 1240, a user interface 1250, and the semiconductor memory device 1210 including the signal delay circuit 100 of FIG. 1 or the signal delay circuit 1000 of FIG. 10. N-bit data (N is an integer equal to or greater than 1) processed or to be processed by the CPU 1230 may be stored in the semiconductor memory device 1210 via a memory controller, or N-bit data requested by the CPU 1230 may be read from the semiconductor memory device 1210 via the memory controller.

The semiconductor memory device 1210 according to the present exemplary embodiment performs an operation according to an output signal OUTSIG that is delayed by the signal delay circuit 100 of FIG. 1 or the signal delay circuit 1000 of FIG. 10. For example, the semiconductor memory device 1210 according to the present exemplary embodiment may perform a read operation for reading data from a memory cell array (not shown) or a write operation for writing data to a memory cell array (not shown), in response to a read command or a write command delayed by the signal delay circuit 100 of FIG. 1 or the signal delay circuit 1000 of FIG. 10.

In the case where the computing system apparatus 1200 according to the present exemplary embodiment is a mobile device, the computing system apparatus 1200 may be additionally provided with a battery and a modem such as a baseband chipset that are arranged to supply an operating voltage of a computing system. In addition, the computing system apparatus 1200 according to the present exemplary embodiment may further be provided with an application chipset, a CMOS image sensor (CIS), a mobile dynamic random access memory (DRAM), or the like.

A signal delay circuit and a semiconductor memory device having the signal delay circuit according to the exemplary embodiments of the inventive concept can maintain a constant delay time even when a power supply voltage, which is supplied from an external source and is directly used as an internal operating voltage of the semiconductor memory device, varies. Accordingly, the signal delay circuit and the semiconductor memory device having the signal delay circuit according to the exemplary embodiments of the inventive concept can prevent malfunctions of the semiconductor memory device, which may occur when the power supply voltage variation causes a delay between internal signals to become distorted.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. A signal delay circuit, comprising:
a delay unit configured to delay an input signal for a first delay time and output the delayed input signal;
a first delay adjusting unit configured to adjust the first delay time according to a variation in a level of a power supply voltage supplied to the delay unit; and
a second delay adjusting unit configured to offset an amount of time the first delay time is adjusted by the first delay adjusting unit.

2. The signal delay circuit of claim 1, wherein the delay unit comprises a plurality of inverters that are connected in series, a first of the series connected inverters being enabled by the input signal or an inverted version of the input signal.

3. The signal delay circuit of claim 2, wherein the first delay adjusting unit comprises a resistor that is connected between the power supply voltage and at least one of the plurality of inverters, or connected between a ground voltage and at least one of the plurality of inverters, wherein a resistance of the resistor varies according to the variation in the voltage level of the power supply voltage.

4. The signal delay circuit of claim 3, wherein the resistance of the resistor decreases when the power supply voltage increases and increases when the power supply voltage decreases.

5. The signal delay circuit of claim 3, wherein the second delay adjusting unit comprises a first metal-oxide-semiconductor (MOS) capacitor and a second MOS capacitor that are connected in series between the ground voltage and an output of at least one of the plurality of inverters, or connected in series between the power supply voltage and an output of at least one of the plurality of inverters.

6. The signal delay circuit of claim 5, wherein a resultant capacitance of the first MOS capacitor and the second MOS capacitor linearly increases while the power supply voltage is shifted from a low voltage level to a high voltage level.

7. The signal delay circuit of claim 5, wherein the first delay time is obtained by multiplying the resistance of the resistor by a resultant capacitance of the first and second MOS capacitors.

8. The signal delay circuit of claim 2, wherein the first delay adjusting unit comprises a resistor that is connected between a ground voltage and at least one of the plurality of inverters, wherein a resistance of the resistor varies according to the variation in the voltage level of the power supply voltage.

9. The signal delay circuit of claim 8, wherein the second delay adjusting unit comprises a first MOS capacitor and a second MOS capacitor that are connected in series between the ground voltage and an output of at least one of the plurality of inverters.

10. The signal delay circuit of claim 8, wherein the second delay adjusting unit comprises a first MOS capacitor through an m^{th} (m is an integer equal to or greater than 3) MOS capacitor that are connected in series between the ground voltage and an output of a last of the series connected inverters that outputs the delayed input signal.

11. The signal delay circuit of claim 2, wherein the first delay adjusting unit comprises a resistor string connected between a ground voltage and a last of the series connected inverters.

12. The signal delay circuit of claim 2, wherein the first delay adjusting unit comprises a resistor that is connected between the power supply voltage and at least one of the plurality of inverters, wherein a resistance of the resistor varies according to the variation in the voltage level of the power supply voltage.

13. The signal delay circuit of claim 12, wherein the second delay adjusting unit comprises a first MOS capacitor and a second MOS capacitor that are connected in series between the power supply voltage and an output of at least one of the plurality of inverters.

14. The signal delay circuit of claim 2, wherein the first delay adjusting unit comprises:
a first resistor that is connected between the power supply voltage and at least one of the plurality of inverters; and
a second resistor that is connected between a ground voltage and at least one of the plurality of inverters to which the first resistor is not connected.

15. The signal delay circuit of claim 14, wherein the second delay adjusting unit comprises:
a first MOS capacitor and a second MOS capacitor that are connected in series between the ground voltage and an output of at least one of the plurality of inverters; and
a third MOS capacitor and a fourth MOS capacitor that are connected in series between the power supply voltage and an output of at least one of the plurality of inverters to which the first MOS capacitor and the second MOS capacitor are not connected.

16. The signal delay circuit of claim 1, wherein the power supply voltage is directly supplied to the signal delay circuit from an external source of a device comprising the signal delay circuit.

17. A signal delay circuit, comprising:
a plurality of unit signal delay circuits that are connected in series, wherein each of the unit signal delay circuits comprises:
a delay unit configured to delay an input signal for a first delay time and output the delayed input signal;
a first delay adjusting unit configured to adjust the first delay time according to a variation in a level of a power supply voltage supplied to the delay unit; and
a second delay adjusting unit configured to offset an amount of time the first delay time is adjusted by the first delay adjusting unit.

18. The signal delay circuit of claim 17, wherein the first delay time of a unit signal delay circuit is the same as the first delay time of another unit signal delay circuit, or the first delay time of a unit signal delay circuit is different than the first delay time of another unit signal delay circuit.

19. A semiconductor memory device, comprising:
a memory cell array; and
a signal delay circuit, comprising:
a delay unit configured to delay an input signal for a first delay time and output the delayed input signal;
a first delay adjusting unit configured to adjust the first delay time according to a variation in a voltage level of a power supply voltage supplied to the delay unit; and
a second delay adjusting unit configured to offset an amount of time the first delay time is adjusted by the first delay adjusting unit;
wherein the semiconductor memory device reads data from the memory cell array or stores data in the memory cell array in response to the signal output from the signal delay circuit.

20. The semiconductor memory device of claim 19, wherein the semiconductor memory device is included in a computing system.
